(19) United States
(12) Patent Application Publication
(10) Pub. No.: US 2026/0107837 A1
(43) Pub. Date: Apr. 16, 2026

(54) SEMICONDUCTOR PACKAGE

(71) Applicant: Samsung Electronics Co., Ltd., Suwon-si (KR)

(72) Inventors: Sungoh AHN, Suwon-si (KR); Junghoon KANG, Suwon-si (KR); Eunkyeong PARK, Suwon-si (KR); Seokbeom YONG, Suwon-si (KR)

(73) Assignee: Samsung Electronics Co., Ltd., Suwon-si (KR)

(21) Appl. No.: 19/211,630

(22) Filed: May 19, 2025

(30) Foreign Application Priority Data
Oct. 15, 2024 (KR) 10-2024-0140541

(51) Int. Cl. H01L 25/18; H01L 23/00; H01L 23/525; H01L 23/64; H01L 25/065; H10B 80/00; H10D 80/30

(52) U.S. Cl. CPC H10W 90/00; H10B 80/00; H10D 80/30; H10W 20/49; H10W 44/00; H10W 72/823; H10W 72/884; H10W 90/297; H10W 90/722; H10W 90/724; H10W 90/732; H10W 90/734; H10W 90/752; H10W 90/754

(57) ABSTRACT

Example embodiments are directed to a semiconductor package for improving Signal Integrity (SI) characteristics. The semiconductor package includes a package substrate, a mediate substrate arranged on the package substrate and including an active layer and a wiring layer, and at least two semiconductor devices on the mediate substrate. The wiring layer includes path wirings configured to connect the at least two semiconductor devices to each other. The path wirings include n paths (n is an integer that is 2 or more), and the active layer includes a selection circuit configured to select one of the n paths.

### CROSS-REFERENCE TO RELATED APPLICATION

This U.S. non-provisional application claims priority under 35 U.S.C. § 119 to Korean Patent Application No. 10-2024-0140541, filed on Oct. 15, 2024, in the Korean Intellectual Property Office, the disclosure of which is incorporated by reference herein in its entirety.

### BACKGROUND

Example embodiments relate to a semiconductor package including a mediate substrate for connecting semiconductor devices to each other.

With the rapid development of the electronics industry and the demands of users, electronic devices are becoming smaller and lighter. As electronic devices become smaller and lighter, semiconductor packages used therein may also be smaller and lighter and may have a relatively higher performance, larger capacity, and/or improved reliability. Semiconductor chips including TSV structures and semiconductor package structures including stacked semiconductor chips may improve miniaturization of semiconductor packages, make the semiconductor packages relatively lighter, and improve performance, storage capacity, and/or reliability of the semiconductor packages. In addition, redistribution substrates or interposers may be used to connect heterogeneous semiconductor chips to each other.

### SUMMARY

Example embodiments of the inventive concepts provide a semiconductor package for improving signal integrity (SI) characteristics.

In addition, the solutions to be achieved by example embodiments of the inventive concepts are not limited to the solutions mentioned above, and other solutions may be clearly understood by one of ordinary skill in the art from the following description.

According to some example embodiments of the inventive concepts, a semiconductor package may include including a package substrate, a mediate substrate arranged on the package substrate and including an active layer and a wiring layer, and at least two semiconductor devices on the mediate substrate. The wiring layer includes path wirings that are configured to connect the at least two semiconductor devices to each other. The path wiring may include n paths (n is an integer that is 2 or more), and the active layer includes a selection circuit configured to select one of the n paths.

According to some example embodiments of the inventive concepts, a semiconductor package may include a package substrate, a mediate substrate arranged on the package substrate and including an active layer and a wiring layer, a first semiconductor device arranged on the mediate substrate, and a second semiconductor device adjacent to the first semiconductor device and arranged on the mediate substrate. The wiring layer includes path wirings that are configured to connect the first semiconductor device and the second semiconductor device to each other. The path wirings may include n paths (n is an integer that is 2 or more), the active layer includes a demultiplexer (DEMUX) connected to the first semiconductor device and a multiplexer (MUX) connected to the second semiconductor device, and one of the n paths is selected through the DEMUX and the MUX. The selected path may have an impedance from a range of impedances.

According to some example embodiments of the inventive concepts, a semiconductor package may include a package substrate, at least two semiconductor devices on the package substrate, and a path substrate including path wirings and a selection circuit, the path wirings connecting the at least two semiconductor devices to each other. The path wirings may include n paths (n is an integer that is 2 or more) and the selection circuit may be configured to select one of the n paths. The semiconductor package has an impedance from a range of impedances that are based on path selection by the selection circuit.

According to some example embodiments, a method of determining impedance of a semiconductor package includes initializing a first value of a path variable, the path variable indicating a number of paths between a first semiconductor device and a second semiconductor device included in the semiconductor package, measuring signal integrity (SI) characteristics for one or more paths corresponding to the first value of the path variable, determining whether the SI characteristic is greater than or equal to a second value in response to the first value of the path variable being less than a total number of paths between the first semiconductor device and the second semiconductor device, and selecting the one or more paths corresponding to the first value in response to the SI characteristic being greater than or equal to a second value. The method further includes increasing the first value to obtain a third value in response to the SI characteristic being less the second value, and measuring the SI characteristics for one or more paths corresponding to the third value. The method still further includes, in response to the first value of the path variable being greater than the total number of paths, selecting one or more paths corresponding to the first value for which the SI characteristic are within a desired threshold.

### BRIEF DESCRIPTION OF THE DRAWINGS

Embodiments will be more clearly understood from the following detailed description taken in conjunction with the accompanying drawings in which:

FIG. 1A is a cross-sectional view of a semiconductor package according to some example embodiments, and FIG. 1B is a lumped circuit diagram illustrating the connection between a first semiconductor device and a second semiconductor device.

FIGS. 2A, 2B, 2C, and 2D are graphs of eye diagrams showing an eye size according to a change in the width of a transmission line in the lumped circuit diagram of FIG. 1B.

FIGS. 3A, 3B, and 3C are cross-sectional views showing a structure of the second semiconductor device in the semiconductor package of FIG. 1A in relative detail.

FIGS. 4A and 4B are cross-sectional views of semiconductor packages according to some example embodiments.

FIGS. 5A and 5B are a perspective view and a cross-sectional view, respectively, of a semiconductor package according to some example embodiments.

FIGS. 6A and 6B are perspective views for explaining the concept of an SoC or chiplet included in the semiconductor package of FIG. 5A.

FIG. 7 is a flowchart schematically showing a method of optimizing the impedance of a semiconductor package, according to some example embodiments.

FIG. 8 is a block diagram illustrating an example computer system for implementing the method and operations illustrated in FIG. 7, and other tasks described herein, according to some example embodiments.

### DETAILED DESCRIPTION OF EXAMPLE EMBODIMENTS

Hereinafter, embodiments of the inventive concept will be described in detail with reference to the accompanying drawings. Like reference numerals are used for the like elements in the drawings, and descriptions thereof are omitted.

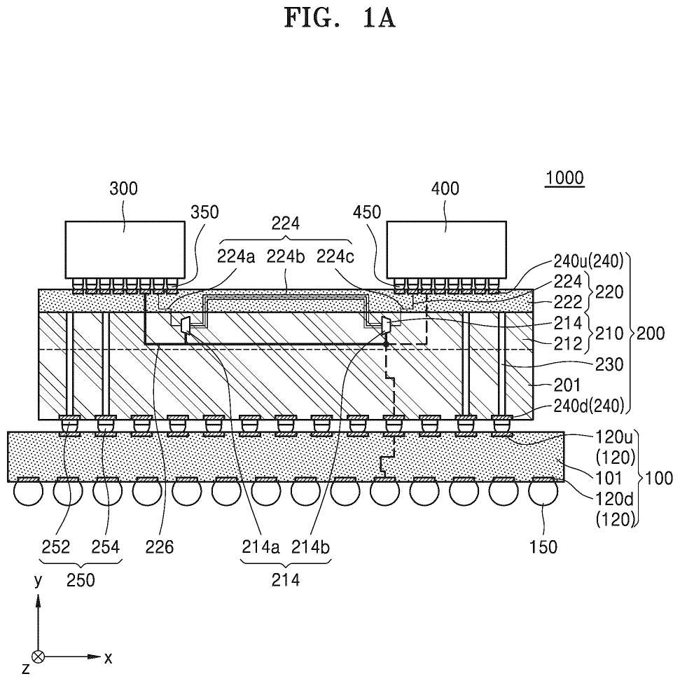

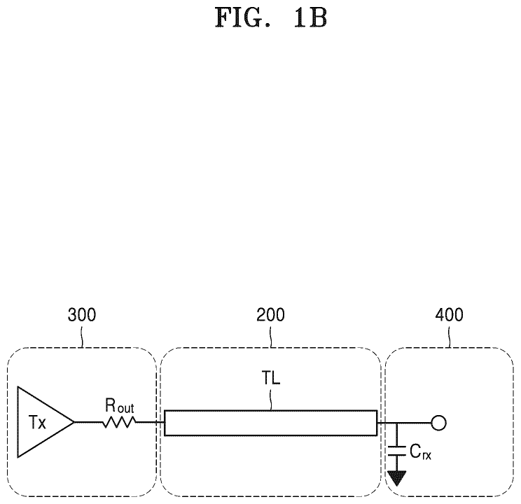

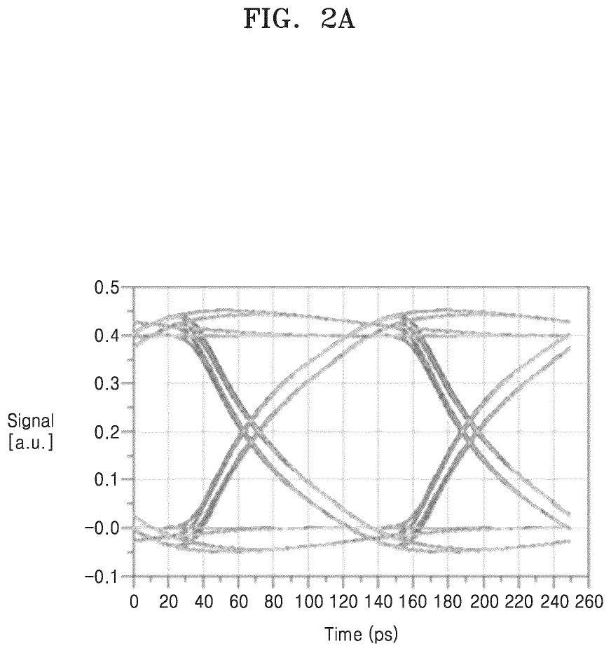

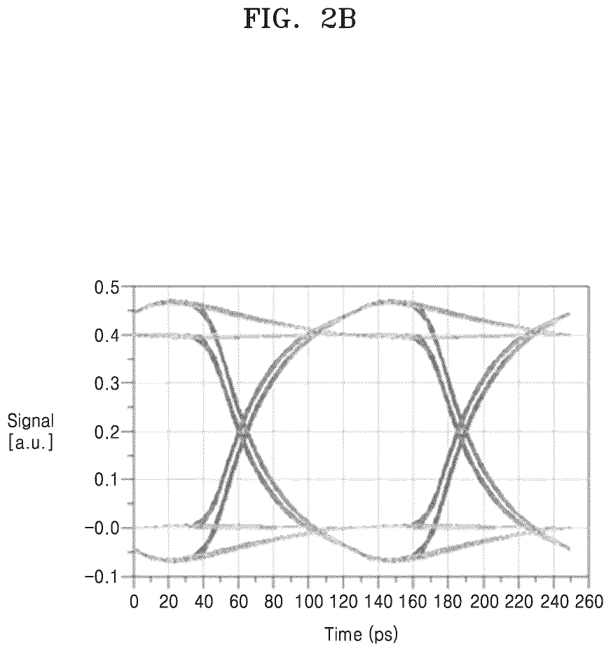

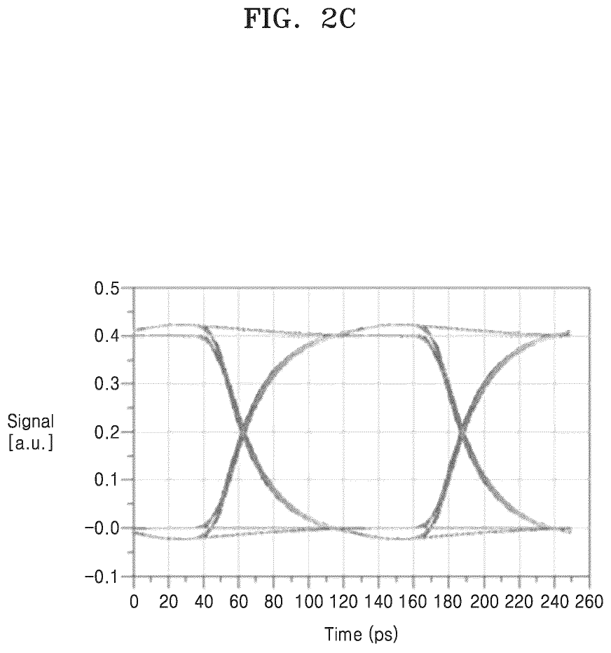

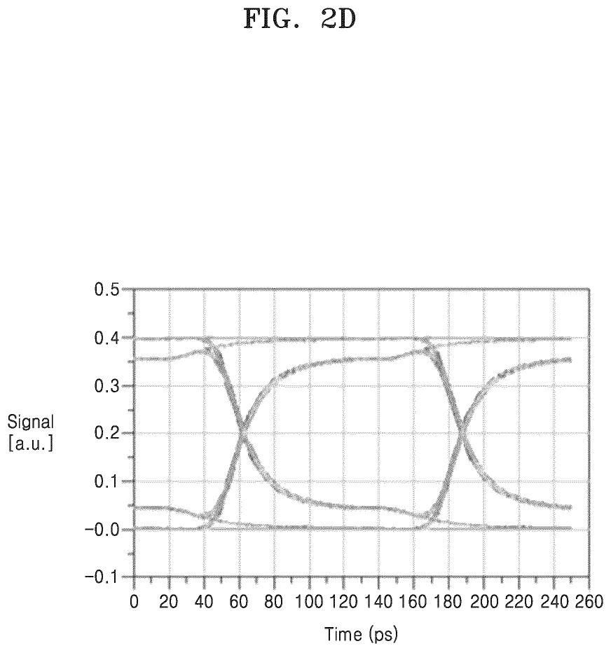

FIG. 1A is a cross-sectional view of a semiconductor package 1000 according to some example embodiments, and FIG. 1B is a lumped circuit diagram showing the connection between a first semiconductor device and a second semiconductor device. FIGS. 2A to 2D are graphs of eye diagrams showing an eye size according to a change in the width of a transmission line in the lumped circuit diagram of FIG. 1B. In FIGS. 2A to 2D, the x-axis represents time and the unit thereof is picoseconds (ps), and the y-axis represents signal voltage and the unit thereof is an arbitrary unit.

Referring to FIGS. 1A to 2D, the semiconductor package 1000, according to some example embodiments, may include a package substrate 100, an interposer 200, a first semiconductor device 300, and/or a second semiconductor device 400.

The package substrate 100 may include, for example, a ceramic substrate, a Printed Circuit Board (PCB), an organic substrate, an interposer substrate, etc. In some example embodiments, the package substrate 100 may include an active wafer, such as a silicon (Si) wafer. In the semiconductor package 1000, according to some example embodiments, the package substrate 100 may include a PCB. However, the package substrate 100 is not limited to a PCB.

The package substrate 100 may include a substrate body layer 101 and a substrate pad 120. The substrate body layer 101 may form or otherwise define the body of the package substrate 100 and may include a wiring layer therein. For example, when the package substrate 100 is a PCB, the substrate body layer 101 may include a core layer and a wiring layer.

The core layer may include, for example, glass fiber and resin such as FR4. In addition or alternatively, the core layer may include a Bismaleimide-Triazine (BT) resin, a Poly Carbonate (PC) resin, a build-up film such as Ajinomoto Build-up Film (ABF), or another laminate resin. In some example embodiments, the core layer may be omitted.

The wiring layer may be distinguished into an upper wiring layer and a lower wiring layer based on the core layer. The upper wiring layer and the lower wiring layer may each include multiple layers of wirings. The number of layers of wirings in the upper wiring layer and the number of layers of wirings in the lower wiring layer may be the same or different. In the semiconductor package 1000, according to some example embodiments, the wiring layer may include 8 to 14 layers of wirings. However, the number of layers of wirings in the wiring layer is not limited to the above numerical range.

The wiring layer may include multiple layers of wirings, an interlayer insulating layer insulating the wirings, and a vertical via connecting the wirings of different layers to each other. The wirings and the vertical via may include, for example, copper (Cu). However, the material of the wirings and the vertical via is not limited to Cu. The interlayer insulating layer may include, for example, prepreg (PPG). However, the material of the interlayer insulating layer is not limited to PPG, and other suitable materials may also be used.

In some example embodiments, the package substrate 100 may be referred to as a redistribution substrate. In some example embodiments, the substrate body layer 101 may not include a separate core layer, but may include an interlayer insulating layer of a Photo-Imageable Dielectric (PID) resin and multilayer wirings.

In some example embodiments, a protective layer may be formed on the upper and lower surfaces of the substrate body layer 101. The protective layer may include, for example, a Solder Resist (SR). However, the material of the protective layer is not limited to the SR.

The substrate pad 120 may include an upper substrate pad 120u on the upper surface of the substrate body layer 101 and a lower substrate pad 120d on the lower surface of the substrate body layer 101. The upper substrate pad 120u may be arranged in a structure that penetrates the protective layer on the upper surface of the substrate body layer 101. In addition, the lower substrate pad 120d may be arranged in a structure that penetrates the protective layer on the lower surface of the substrate body layer 101. The upper substrate pad 120u and the lower substrate pad 120d may each be connected to the wirings of the substrate body layer 101. External connection terminals 150 may be arranged on the lower substrate pad 120d, and first connection terminals 250 may be arranged on the upper substrate pad 120u. In some example embodiments, the substrate pad 120 may be treated as a part of the wirings of the wiring layer.

The external connection terminals 150 may connect the semiconductor package 1000 to a package substrate of an external system, or a main board of an electronic device, such as a mobile device. Each of the external connection terminals 150 may include at least one of conductive materials, for example, solder, tin (Sn), silver (Ag), copper (Cu), and aluminum (Al). However, the material of the external connection terminal 150 is not limited to the aforementioned materials.

The interposer 200 may be mounted or installed on the package substrate 100 through a first connection terminal 250. The first connection terminal 250 may include, for example, a pillar 252 and a bump 254. In some example embodiments, the first connection terminal 250 may include only solder. The pillar 252 may have a cylindrical shape and may include, for example, nickel (Ni), copper (Cu), palladium (Pd), platinum (Pt), gold (Au), or a combination thereof. In the semiconductor package 1000, according to some example embodiments, the pillar 252 may include Cu.

The bump 254 may be arranged on the pillar 252. The bump 254 may include, for example, solder. The solder may include tin (Sn), indium (In), bismuth (Bi), antimony (Sb), copper (Cu), silver (Ag), zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc. In some example embodiments, the bump 254 may be referred to as solder, solder bump, etc.

The interposer 200 may be arranged between the package substrate 100 and the first semiconductor device 300 and between the package substrate 100 and the second semiconductor device 400. For example, the first semiconductor device 300 and the second semiconductor device 400 may be arranged on the interposer 200, and the interposer 200 may be configured to mediate signal transmission between the first semiconductor device 300 and the second semiconductor device 400. In addition or alternatively, the interposer 200 may mediate or communicate or transfer the transmission of signals, power, etc. between the first semiconductor device 300 and the package substrate 100 and between the second semiconductor device 400 and the package substrate 100. In some example embodiments, the interposer 200 may be referred to as a mediate substrate.

The interposer 200 may include an interposer body layer 201, an active layer 210, a wiring layer 220, a through-electrode 230, and an interposer pad 240. The interposer body layer 201 may include, for example, Si. Accordingly, the interposer 200 may be referred to as a Si-interposer. In some example embodiments, the active layer 210 and the wiring layer 220 may be combined and referred to as an active layer. In some example embodiments, the interposer 200 including the active layer 210 and the wiring layer 220 may be referred to as a path substrate.

The active layer 210 may be arranged on the interposer body layer 201. The active layer 210 may be formed by doping an upper portion of the interposer body layer 201 with impurities. The active layer 210 may include an impurity layer 212 and a selection circuit 214. The selection circuit 214 may include semiconductor elements, such as a diode and a transistor. For example, in the semiconductor package 1000, according to some example embodiments, the selection circuit 214 may include a multiplexer (MUX) 214b and a demultiplexer (DEMUX) 214a.

For reference, MUX is an abbreviation for a multiplexer and may refer to a combinational logic circuit that selects one of several input lines and connects the selected input line to an output line. The MUX 214b may be referred to as a data selector based on the function thereof. DEMUX is an abbreviation for a demultiplexer and may perform the opposite function of a multiplexer. The DEMUX 214a may refer to a combinational logic circuit that selects one of several output lines and connects one input line to the selected output line.

The wiring layer 220 may be arranged on the active layer 210 and may include an interlayer insulating layer 222 and wirings 224. The wirings 224 may connect the first semiconductor device 300 and the second semiconductor device 400 to each other. In addition or alternatively, the wirings 224 may connect the through-electrode 230 and the interposer pad 240, that is, an upper interposer pad 240u, to each other.

The wirings 224 may include a first wiring 224a connected to the first semiconductor device 300, a path wiring 224b between the first semiconductor device 300 and the second semiconductor device 400, and a second wiring 224c connected to the second semiconductor device 400. For example, the DEMUX 214a may be connected to the first semiconductor device 300 through the first wiring 224a. In addition, the MUX 214b may be connected to the second semiconductor device 400 through the second wiring 224c. The DEMUX 214a and the MUX 214b may be connected to each other through the path wiring 224b.

For reference, based on the concept of transmitting a signal from the first semiconductor device 300 to the second semiconductor device 400, as indicated in the lumped circuit diagram of FIG. 1B, the DEMUX 214a and the MUX 214b may be arranged as in FIG. 1A. However, when a signal is to be transmitted from the second semiconductor device 400 to the first semiconductor device 300, the positions of the DEMUX 214a and the MUX 214b may be interchanged.

The through-electrode 230 may extend through the interposer body layer 201. Because the interposer body layer 201 includes Si, the through-electrode 230 may correspond to or maybe referred to as a Through Silicon Via (TSV). The through-electrode 230 may extend to the wiring layer 220 and be connected to the wirings 224 of the wiring layer 220. In addition or alternatively, the through-electrode 230 may be connected to the first connection terminal 250 on the lower surface of the interposer body layer 201 through the interposer pad 240, i.e., a lower interposer pad 240d.

The interposer pad 240 may include the upper interposer pad 240u on the upper surface of the wiring layer 220 and the lower interposer pad 240d on the lower surface of the interposer body layer 201. The upper interposer pad 240u may be connected to the wirings 224 of the wiring layer 220. In addition or alternatively, a second connection terminal 350 of the first semiconductor device 300 and a third connection terminal 450 of the second semiconductor device 400 may be arranged on the upper interposer pad 240u. The lower interposer pad 240d may be connected to the through-electrode 230. In addition or alternatively, the first connection terminal 250 may be arranged on the lower interposer pad 240d.

In the semiconductor package 1000, according to some example embodiments, the interposer 200 may be an interposer for a 2.5D package. For reference, the interposer 200 may largely include an interposer for a 2.5D package and an interposer for a 2.3D package. The interposer for a 2.5D package may refer to a Si-interposer and may include a TSV therein. The interposer for a 2.3D package may refer to an organic or inorganic interposer. In the case of an organic interposer, PolyImide (PI), BenzoCycloButene (BCB), or PolyBenzOxazole (PBO) may be used as a body layer, and in the case of an inorganic interposer, ceramic or glass may be used as a body layer. In the case where the interposer for a 2.3D package includes a through-electrode, the through-electrode may be referred to as a Through Dielectric Via (TDV), a Through Glass Via (TGV), etc. depending on the material of the body layer.

The first semiconductor device 300 may be mounted on the interposer 200 via the second connection terminal 350. As seen in FIG. 1A, the first semiconductor device 300 may be arranged on the left side of the interposer 200 in the x direction. However, the position of the first semiconductor device 300 is not limited thereto. For example, the first semiconductor device 300 may be arranged on the right side of the interposer 200 in the x direction.

The first semiconductor device 300 may have a chip or package structure. In the semiconductor package 1000, according to some example embodiments, the first semiconductor device 300 may have a chip structure. For example, the first semiconductor device 300 may include a logic chip. The first semiconductor device 300 may include a plurality of logic devices therein. The logic devices may include, for example, an AND, a NAND, an OR, a NOR, an exclusive OR (XOR), an exclusive NOR (XNOR), an inverter (INV), an adder (ADD), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, a counter, or buffer elements. The logic devices may perform various signal processing, such as analog signal processing, Analog-to-Digital Conversion (A/D conversion), and control. The first semiconductor device 300 may be referred to as a Central Processing Unit (CPU) chip, a System-On-Glass (SOG) chip, a Micro-Processor Unit (MPU) chip, a Graphics Processing Unit (GPU) chip, a Neural Processing Unit (NPU) chip, an Application Processor (AP) chip, or a control chip, depending on the function of the first semiconductor device 300.

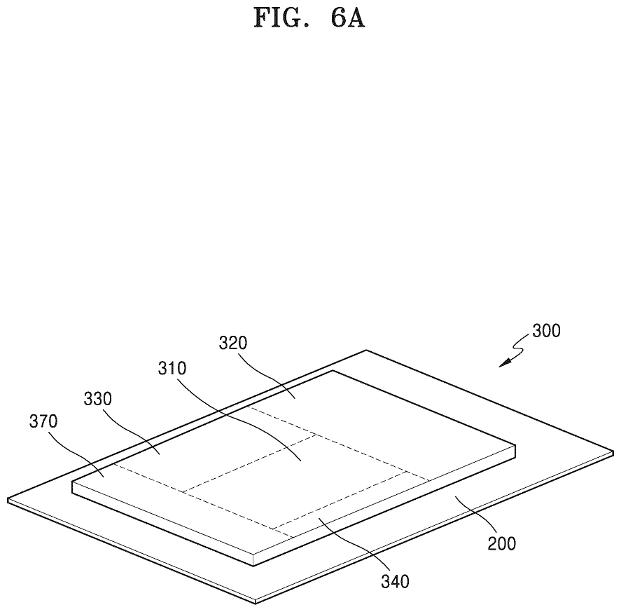

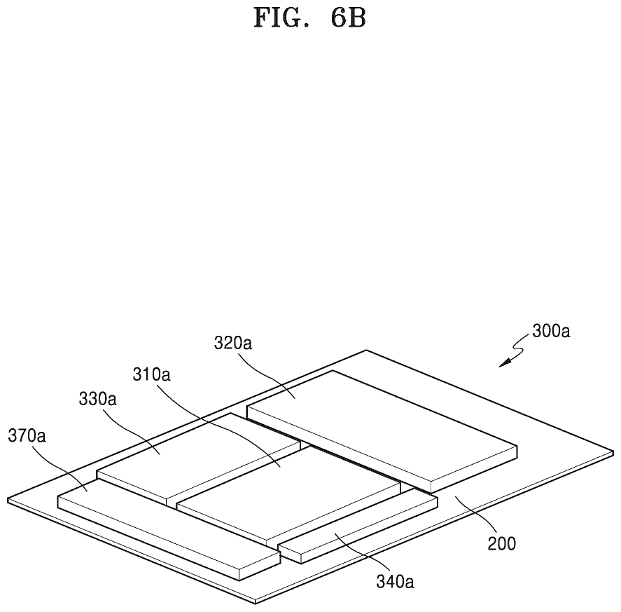

In the semiconductor package 1000, according to some example embodiments, the first semiconductor device 300 may have a chip structure, but may have a System on Chip (SoC) structure or a chiplet structure. The SoC structure and the chiplet structure of the first semiconductor device 300 will be described in more detail below with reference to FIGS. 6A and 6B.

The first semiconductor device 300 may also include devices that may be used to communication. However, in some example embodiments, devices for communication may be provided separately as another chip, for example, a modem chip, and may be arranged on the interposer 200 with a structure coupled to the first semiconductor device 300.

The first semiconductor device 300 may include a first chip body and a first active layer. The first chip body may constitute the body of the first semiconductor device 300 and may include Si. However, the material of the first chip body is not limited to Si. For example, the first chip body may include another semiconductor material, such as germanium (Ge) or Si—Ge, or a III-V group compound, such as GaP, GaAs, or GaSb. In addition, in some example embodiments, the first chip body may include a silicon-on-insulator (SOI) substrate, or a germanium-on-insulator (GOI) substrate.

The first active layer may be arranged below the first chip body and may include a first integrated circuit layer and a first wiring layer. The first integrated circuit layer may include a plurality of first integrated elements. The first integrated element may include, for example, a transistor. However, the first integrated element is not limited to a transistor. The first wiring layer may be arranged below the first integrated circuit layer. The first wiring layer may include an interlayer insulating layer, wirings, and a chip pad. The wirings may be arranged in two or more layers, and wirings of different layers may be connected to each other through vertical vias. When comparing the first semiconductor device 300 with the interposer 200, the first integrated circuit layer may correspond to the active layer 210 and the first wiring layer may correspond to the wiring layer 220.

In the first semiconductor device 300, the lower surface may be the front surface, which may be referred to as an active surface, and the upper surface may be the back surface, which may be referred to as an inactive surface. In other words, the lower side where a wiring layer is arranged based on the first chip body may correspond to the front surface of the first semiconductor device 300, and the upper side of the first chip body may correspond to the back surface of the first semiconductor device 300.

The second semiconductor device 400 may be mounted on the interposer 200 via the third connection terminal 450. As is seen from FIG. 1A, the second semiconductor device 400 may be arranged on the right side of the interposer 200 in the x direction. However, the position of the second semiconductor device 400 is not limited thereto. For example, when the first semiconductor device 300 is arranged on the right side of the interposer 200 in the x direction, the second semiconductor device 400 may be arranged on the left side of the interposer 200 in the x direction.

The second semiconductor device 400 may include logic devices or memory devices When the second semiconductor device 400 includes logic devices, the second semiconductor device 400 may include memory devices that support communication of the first semiconductor device 300. For example, the second semiconductor device 400 may include a modem chip. However, the type of the second semiconductor device 400 is not limited to a modem chip. For example, the second semiconductor device 400 may include various types of logic devices that support the operation of the first semiconductor device 300 or for various signal processing together with the first semiconductor device 300.

When the second semiconductor device 400 includes memory devices, the second semiconductor device 400 may include, for example, a volatile memory device, such as Dynamic Random Access Memory (DRAM) or Static Random Access Memory (SRAM), or a nonvolatile memory device, such as flash memory. In addition, when the second semiconductor device 400 includes memory devices, the second semiconductor device 400 may have a single chip structure or a package structure.

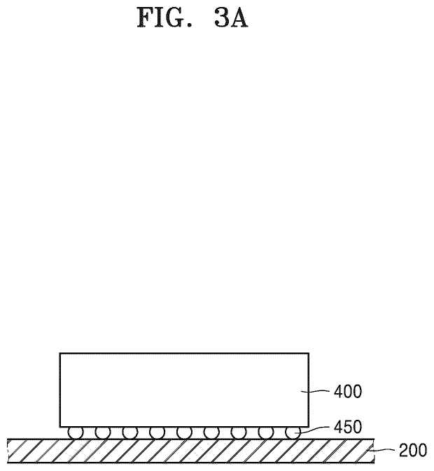

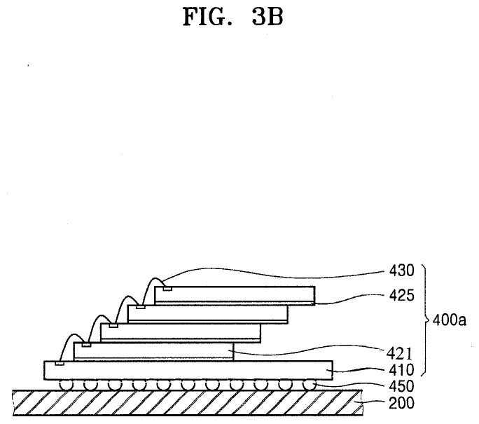

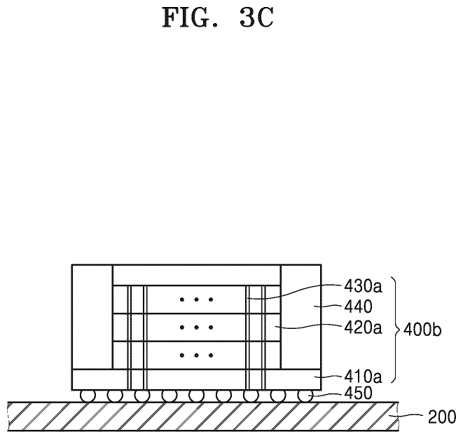

In the semiconductor package 1000, according to some example embodiments, the second semiconductor device 400 may include, for example, a High Bandwidth Memory (HBM) package. However, the second semiconductor device 400 is not limited to an HBM package. For example, the second semiconductor device 400 may have a general package structure. For example, the second semiconductor device 400 may include an upper package substrate and a plurality of memory chips stacked on the upper package substrate. In addition, the memory chips may be stacked on the upper package substrate through bonding wires, or may be stacked on the upper package substrate through bumps and TSVs. The single chip structure or the package structure of the second semiconductor device 400 will be described below with reference to FIGS. 3A to 3C.

The second semiconductor device 400 may include a second chip body and a second active layer. The second chip body may constitute the body of the second semiconductor device 400 and may include Si. However, the material of the second chip body is not limited to Si. The second active layer may be arranged below the second chip body and may include a second integrated circuit layer and a second wiring layer. The second integrated circuit layer may include a plurality of second integrated elements. The second integrated element may include, for example, a transistor. However, the second integrated element is not limited to a transistor. The second chip body and the second active layer are as described in the description of the first chip body and the first active layer of the first semiconductor device 300. In the second semiconductor device 400, the lower surface may be the front surface, which may be referred to an active surface, and the upper surface may be the back surface, which may be referred to as an inactive surface. In other words, the lower side where a wiring layer is arranged based on the second chip body may correspond to the front surface of the second semiconductor device 400, and the upper side of the second chip body may correspond to the back surface of the second semiconductor device 400.

The lumped circuit diagram of FIG. 1B shows the connection relationship between the first semiconductor device 300 and the second semiconductor device 400. In the lumped circuit diagram, assuming that the first semiconductor device 300 outputs a transmission signal and the second semiconductor device 400 receives the transmission signal, the first semiconductor device 300 is represented as a transmission circuit Tx and an output resistance Rₒᵤₜ, and the second semiconductor device 400 is represented as an input capacitance Cᵣₓ. In addition, the wirings 224 in the interposer 200 between the first semiconductor device 300 and the second semiconductor device 400 are represented as a transmission line TL. The semiconductor package 1000 according to some example embodiments may optimize impedance matching by changing the impedance of the transmission line TL by changing a path through the selection circuit 214 of the interposer 200.

In some example embodiments, the selection circuit 214 may include the DEMUX 214a and the MUX 214b, and there may be n paths (n is an integer that is 2 or more) between the DEMUX 214a and the MUX 214b. In addition, transmission lines TL of the n paths may have different lengths, widths, etc. Therefore, by selecting and changing one of the n paths through the DEMUX 214a and the MUX 214b, the impedance of the transmission line TL may be changed. As described above, the wirings 224 of the wiring layer 220 may include the first wiring 224a connected to the first semiconductor device 300, the path wiring 224b between the first semiconductor device 300 and the second semiconductor device 400, and the second wiring 224c connected to the second semiconductor device 400. The transmission line TL may include the first wiring 224a, the path wiring 224b, and the second wiring 224c, but the impedance of the transmission line TL may be substantially changed through the path wiring 224b.

A control wiring 226 may be connected to the DEMUX 214a and the MUX 214b. A control signal may be applied to the DEMUX 214a and the MUX 214b through the control wiring 226 to control the path selection. The control wiring 226 may be connected to the first semiconductor device 300, as indicated by the thick solid line in FIG. 1A. However, the disclosure is not limited thereto, and as indicated by the thick dashed line in FIG. 1A, the control wiring 226 may also be connected to the second semiconductor device 400, or the external connection terminal 150 of the package substrate 100. Therefore, a control signal may be applied to the DEMUX 214a and the MUX 214b through the first semiconductor device 300, the second semiconductor device 400, or the external connection terminal 150 of the package substrate 100.

FIGS. 2A to 2D show eye diagrams when, through simulation, the length of the transmission line TL is fixed (e.g., kept constant) and the width of the transmission line TL is changed to vary the impedance. As an example, in FIGS. 2A to 2D, when the width of the transmission line TL is 1 μm (or about 1 μm), 5 μm (or about 5μm), 10 μm (or about 10 μm), and 20 μm (or about 20 μm), respectively, the impedance may be 79.6 Ω (or about 79.6 Ω), 56 Ω (or about 56 Ω), 43 Ω (or about 43 Ω), and 31.2 Ω (or about 31.2 Ω), respectively. Therefore, based on the eye size, it may be predicted that FIG. 2C may correspond to an impedance condition having optimal impedance.

In addition, impedance mismatch may occur due to impedance variation of the transmission line TL due to process tolerance of the interposer 200, variation of chips constituting the first semiconductor device 300 and the second semiconductor device 400, signal skew due to signal routing constraints, and the like, and target Signal Integrity (SI) characteristics may deteriorate, for example, after packaging, due to the impedance mismatch. Therefore, as in the cases of FIGS. 2A, 2B, and 2D above, a decrease in the margin relative to the target SI characteristics may occur. The variation of chips may include process variation, voltage variation, temperature variation, etc. of a receive/transmit (Rx/Tx) circuit within a chip.

In the semiconductor package 1000 according to some example embodiments, the interposer 200 may include the active layer 210 and the wiring layer 220. In addition or alternatively, the selection circuit 214 may be arranged in the active layer 210, and n path wirings 224b may be arranged in the wiring layer 220. The semiconductor package 1000 according to some example embodiments may optimize impedance by selecting and changing the path wiring 224b through the selection circuit 214. Accordingly, a relatively higher performance semiconductor package may be obtained by reducing SI characteristic degradation and margin reduction due to impedance variation of the transmission line TL due to tolerance, variation of chips, signal skew, and the like. In some example embodiments, the SI characteristics may be improved by reducing the impedance, which in turn reduces signal delay.

In the semiconductor package 1000, according to some example embodiments, the first semiconductor device 300 and the second semiconductor device 400 are arranged on the interposer 200 and signal transmission is performed between the first semiconductor device 300 and the second semiconductor device 400 through path selection by the selection circuit 214. However, the semiconductor package 1000 is not limited thereto. For example, three or more semiconductor devices may be arranged on the interposer 200, and signal transmission may be performed between the three or more semiconductor devices through path selection by the selection circuit 214. However, even in the case of signal transmission between three or more semiconductor devices, signal transmission between two semiconductor devices of the three or more semiconductor devices may be substantially the same as the signal transmission between the first semiconductor device 300 and the second semiconductor device 400.

FIGS. 3A to 3C are cross-sectional views showing the structure of the second semiconductor device 400 in the semiconductor package 1000 of FIG. 1A in relative more detail. Descriptions already given above with reference to FIGS. 1A to 2D are not repeated for sake of brevity and like numerals indicate like elements not described again in detail.

Referring to FIG. 3A, the second semiconductor device 400 may include one memory chip. The memory chip may include, for example, a volatile memory device, such as DRAM or SRAM, or a nonvolatile memory device, such as flash memory. In the semiconductor package 1000 according to some example embodiments, the memory chip of the second semiconductor device 400 may include, for example, a DRAM chip. The second semiconductor device 400 may be mounted on the interposer 200 with a flip-chip bonding structure using the third connection terminal 450. The third connection terminal 450 may include a metal pillar and solder, or may include only solder.

Referring to FIG. 3B, a second semiconductor device 400a may include a semiconductor package having a wire bonding structure. In some example embodiments, the second semiconductor device 400a may include a package substrate 410 and a plurality of memory chips 421 stacked on the package substrate 410. The memory chips 421 may be mounted on the package substrate 410 with a wire bonding structure using an adhesive layer 425 and a wire 430. The memory chip 421 of the second semiconductor device 400a may include, for example, a volatile memory device, such as DRAM or SRAM, or a nonvolatile memory device, such as flash memory. In the semiconductor package 1000 according to some example embodiments, the memory chip 421 of the second semiconductor device 400a may include, for example, a DRAM chip. The second semiconductor device 400a may include an internal sealant that seals the memory chip 421 and the wire 430 on the package substrate 410. However, in FIG. 3B, the internal sealant is omitted for convenience.

In FIG. 3B, four memory chips 421 are stacked on the package substrate 410, but the number of memory chips 421 is not limited to four. For example, 3 or less or 5 or more memory chips 421 may be stacked on the package substrate 410 In addition, the memory chip 421 is not limited to a step structure and may be stacked on the package substrate 410 in a zigzag structure, or a structure in which the step structure and the zigzag structure are combined. A third connection terminal 450 may be arranged on the lower surface of the package substrate 410. Accordingly, the second semiconductor device 400a of the package structure may also be mounted on the interposer 200 via the third connection terminal 450.

Referring to FIG. 3C, a second semiconductor device 400b may include an HBM package. In some example embodiments, the second semiconductor device 400b may include a base chip 410a, a plurality of core chips 420a stacked on the base chip 410a, and an internal sealant 440. In addition, the base chip 410a and the core chips 420a may include a through-electrode 430a therein. However, the uppermost core chip 420a among the core chips 420a may not include the through-electrode 430a.

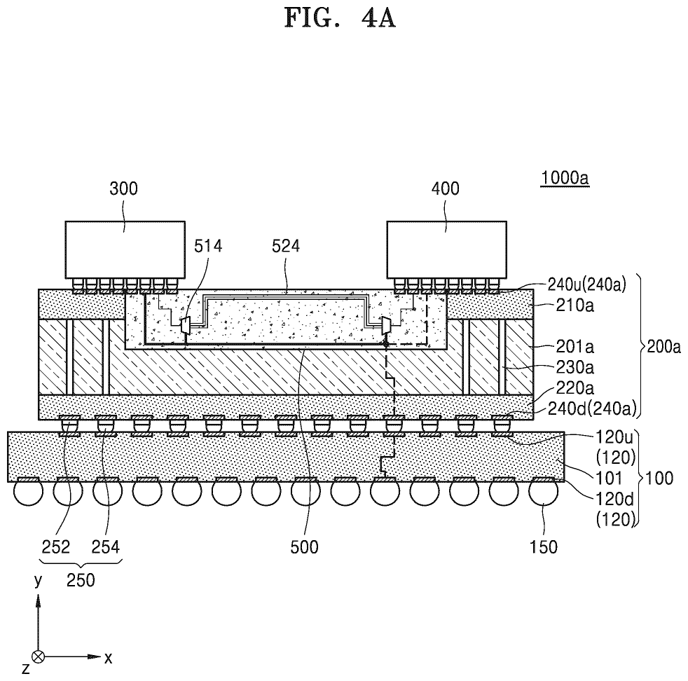

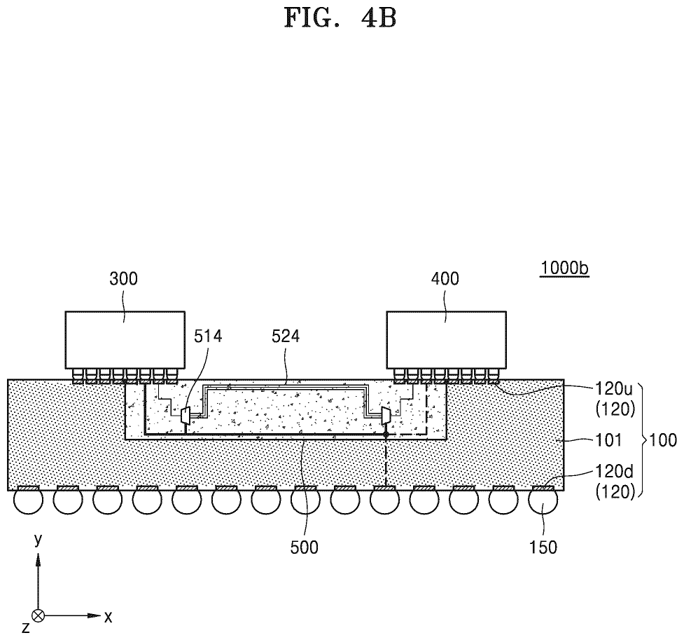

The base chip 410a may include logic devices. Accordingly, the base chip 410a may be referred to as a logic chip. The base chip 410a may be arranged below the core chips 420a, integrate signals of the core chips 420a and transmit the signals to the outside, and also transmit signals and power from the outside to the core chips 420a. Accordingly, the base chip 410a may be referred to as a buffer chip or a control chip. Each of the core chips 420a may be or include a memory chip. For example, each of the core chips 420a may be a DRAM chip. The core chip 420a may be stacked on the base chip 410a or a lower core chip 420a through pad-to-pad bonding, hybrid bonding (HB), bonding using a connection terminal, or bonding using anisotropic conductive film (ACF). In FIGS. 3C, 4 core chips 420a are stacked on the base chip 410a, but the number of core chips 420a is not limited to four. For example, 3 or less or 5 or more core chips 420a may be stacked on the base chip 410a.

A third connection terminal 450 may be arranged on the lower surface of the base chip 410a. Accordingly, the second semiconductor device 400b of the HBM package may also be mounted on the interposer 200 through the third connection terminal 450. The core chips 420a on the base chip 410a may be sealed by the internal sealant 440. However, the upper surface of the uppermost core chip 420a among the core chips 420a may not be covered by the internal sealant 440. However, in some example embodiments, the upper surface of the uppermost core chip 420a may be covered by the internal sealant 440.

FIGS. 4A and 4B are cross-sectional views of semiconductor packages 1000a and 1000b according to some example embodiments. The semiconductor packages 1000a and 1000b may be same as or similar in some respects to the semiconductor packages 1000 of FIGS. 1A-3C, and therefore may be best understood with reference thereto where like numerals indicate like elements not described again in detail.

Referring to FIG. 4A, the semiconductor package 1000a according to some example embodiments may include a different type of an interposer 200a, and may further includes a Si-bridge 500. In some example embodiments, the semiconductor package 1000a according to some example embodiments may include a package substrate 100, an interposer 200a, a first semiconductor device 300, a second semiconductor device 400, and a Si-bridge 500. The package substrate 100, the first semiconductor device 300, and the second semiconductor device 400 are same as or similar in some respects to the semiconductor package 1000 of FIG. 1A, and may be best understood with respect thereto.

The interposer 200a may be arranged between the package substrate 100 and the first semiconductor device 300 and between the package substrate 100 and the second semiconductor device 400. For example, the first semiconductor device 300 and the second semiconductor device 400 may be arranged on the interposer 200a, and the interposer 200a may mediate signal transmission between the first semiconductor device 300 and the second semiconductor device 400. In addition, the interposer 200a may mediate the transmission of signals, power, etc. between the first semiconductor device 300 and the package substrate 100 and between the second semiconductor device 400 and the package substrate 100. In the semiconductor package 1000a according to some example embodiments, the interposer 200a may be an interposer for a 2.3D package. In some example embodiments, the interposer 200a may be referred to as a Panel Level Package (PLP) interposer, a Re-Distribution Layer (RDL) interposer, etc.

In the semiconductor package 1000a according to some example embodiments, the interposer 200a may include an interposer body layer 201a, an upper redistribution layer 210a, a lower redistribution layer 220a, a through-electrode 230a, and an interposer pad 240a. The interposer body layer 201a may include an organic or inorganic material. For example, the interposer body layer 201a may include PI, BCB, PBO, ceramic, glass, or the like. However, the material of the interposer body layer 201a is not limited to the aforementioned materials.

The upper redistribution layer 210a may be arranged on the interposer body layer 201a. The upper redistribution layer 210a may be connected to the front surfaces, which are active surfaces, of the first semiconductor device 300 and the second semiconductor device 400. Accordingly, the upper redistribution layer 210a may be referred to as a front redistribution layer. The upper redistribution layer 210a may include an upper interlayer insulating layer and upper redistribution lines. The upper interlayer insulating layer may include an insulating material, for example, a PID or Photo Imageable Polyimide (PIP) resin, and may further include an inorganic filler. However, the material of the upper interlayer insulating layer is not limited to the aforementioned materials. For example, the upper interlayer insulating layer may include Polymide Isoindro Quirazorindione (PIQ), PI, PBO, or the like.

The upper redistribution lines may be arranged in multiple layers within the upper interlayer insulating layer. The upper redistribution lines of different layers may be connected to each other by vertical vias. The upper redistribution lines and the vertical vias may include, for example, copper (Cu). However, the material of the upper redistribution lines and the vertical vias is not limited to Cu.

The lower redistribution layer 220a may be arranged below the interposer body layer 201a. The lower redistribution layer 220a may be referred to as a back redistribution layer. The lower redistribution layer 220a may include a lower interlayer insulating layer and lower redistribution lines. The lower interlayer insulating layer and the lower redistribution lines may be same as or similar in some respects to the upper interlayer insulating layer and upper redistribution lines of the upper redistribution layer 210a. In some example embodiments, at least one of the upper redistribution layer 210a and the lower redistribution layer 220a may be omitted.

The through-electrode 230amay be arranged between the upper redistribution layer 210a and the lower redistribution layer 220a. Because the interposer body layer 201a is arranged between the upper redistribution layer 210a and the lower redistribution layer 220a, the through-electrode 230a may have a structure extending through the interposer body layer 201a. The through-electrode 230amay electrically connect the upper redistribution layer 210a to the lower redistribution layer 220a. For example, the upper surface of the through-electrode 230amay be connected to the upper redistribution line of the upper redistribution layer 210a, and the lower surface of the through-electrode 230amay be connected to the lower redistribution line of the lower redistribution layer 220a. When the upper redistribution layer 210a or the lower redistribution layer 220a is omitted, the through-electrode 230amay be directly connected to the interposer pad 240a. The through-electrode 230amay include, for example, Cu. However, the material of the through-electrode 230ais not limited to Cu. In some example embodiments, the through-electrode 230amay be referred to as TDV, TGV, etc., depending on the material of the interposer body layer 201a.

The interposer pad 240a may include an upper interposer pad 240u on the upper surface of the upper redistribution layer 210a and a lower interposer pad 240d on the lower surface of the lower redistribution layer 220a. The upper interposer pad 240u may be connected to the upper redistribution lines of the upper redistribution layer 210a. In addition, a second connection terminal 350 of the first semiconductor device 300 and a third connection terminal 450 of the second semiconductor device 400 may be arranged on the upper interposer pad 240u. The lower interposer pad 240d may be connected to the lower redistribution lines of the lower redistribution layer 220a. In addition, a first connection terminal 250 may be arranged on the lower interposer pad 240d. In some example embodiments, the upper interposer pad 240u may be treated as a part of the upper redistribution lines, and the lower interposer pad 240d may be treated as a part of the lower redistribution lines. In addition, as described above, when the upper redistribution layer 210a or the lower redistribution layer 220a is omitted, the upper interposer pad 240u or the lower interposer pad 240d may be directly connected to the through-electrode 230.

The Si-bridge 500 may be arranged inside the interposer 200a. The Si-bridge 500 may connect the first semiconductor device 300 to the second semiconductor device 400. Accordingly, the Si-bridge 500 may be arranged inside the interposer 200a between the first semiconductor device 300 and the second semiconductor device 400. In addition, the Si-bridge 500 may overlap a part of the first semiconductor device 300 and a part of the second semiconductor device 400.

The Si-bridge 500 may be arranged in the interposer body layer 201a of the interposer 200a, as shown in FIG. 4A, and a part of the interposer body layer 201a may be maintained below the Si-bridge 500. However, in some example embodiments, the Si-bridge 500 may be arranged on the lower redistribution layer 220a and the interposer body layer 201a may not be between the Si-bridge 500 and the lower redistribution layer 220a.

The Si-bridge 500 may include a selection circuit 514 and wirings 524. The selection circuit 514 and the wirings 524 are as described for the selection circuit 214 and the wirings 224 in the semiconductor package 1000 of FIG. 1A, except that the selection circuit 514 and the wirings 524 are arranged in the Si-bridge 500 instead of the interposer 200. In some example embodiments, the Si-bridge 500 may be distinguished into an active layer and a wiring layer, and the selection circuit 514 may be arranged in the active layer and the wirings 524 may be arranged in the wiring layer.

As a result, in the semiconductor package 1000a according to some example embodiments, the Si-bridge 500 may be arranged in the interposer 200a and may include the selection circuit 514 and the wirings 524 that form n paths. Accordingly, the semiconductor package 1000a according to some example embodiments may implement a high-performance semiconductor package by reducing SI characteristic degradation and margin reduction by selecting one of the n paths through the selection circuit 514 to optimize impedance.

Referring to FIG. 4B, the semiconductor package 1000B according to some example embodiments may be different from the semiconductor package 1000 of FIG. 1A in that the interposer 200 is omitted and a Si-bridge 500 is further included in the semiconductor package 1000B. The semiconductor package 1000b according to some example embodiments may include a package substrate 100, a first semiconductor device 300, a second semiconductor device 400, and the Si-bridge 500. The package substrate 100, the first semiconductor device 300, and the second semiconductor device 400 may be same as or similar in some respects to the semiconductor package 1000 of FIG. 1A.

In the semiconductor package 1000b according to some example embodiments, the interposer may be omitted, and the first semiconductor device 300 and the second semiconductor device 400 may be mounted directly on the package substrate 100. In addition, the first semiconductor device 300 and the second semiconductor device 400 may be connected to each other through the Si-bridge 500 arranged in the package substrate 100.

The Si-bridge 500 may be arranged in the substrate body layer 101, as illustrated in FIG. 4B. In addition, the Si-bridge 500 may include a selection circuit 514 and wirings 524. The selection circuit 514 and the wirings 524 may be same as or similar in some respects to the selection circuit 214 and the wirings 224 in the semiconductor package 1000 of FIG. 1A, except that the selection circuit 514 and the wirings 524 are arranged in the Si-bridge 500 instead of the interposer 200. In some example embodiments, the Si-bridge 500 may be distinguished into an active layer and a wiring layer, and the selection circuit 514 may be arranged in the active layer and the wirings 524 may be arranged in the wiring layer.

As a result, in the semiconductor package 1000b according to some example embodiments, the Si-bridge 500 may be arranged in the package substrate 100 and may include the selection circuit 514 and the wirings 524 of n-paths. Accordingly, the semiconductor package 1000b according to some example embodiments may implement a high-performance semiconductor package by reducing SI characteristic degradation and margin reduction by selecting one of the n paths through the selection circuit 514 to optimize impedance.

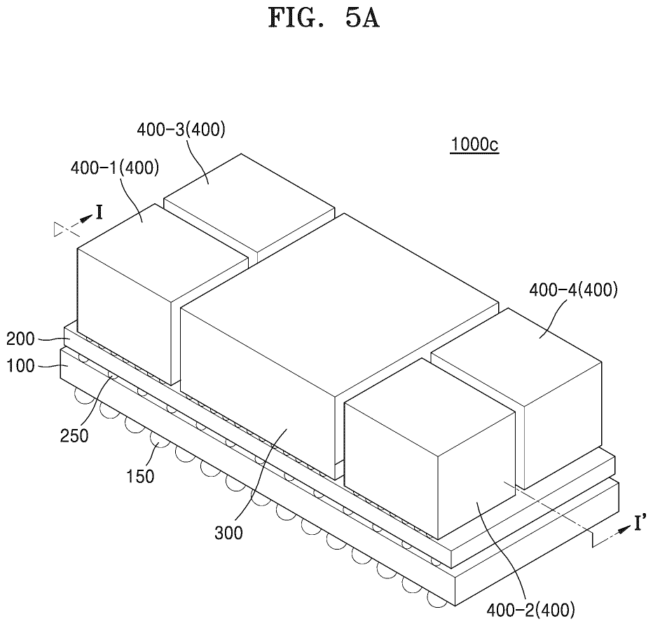

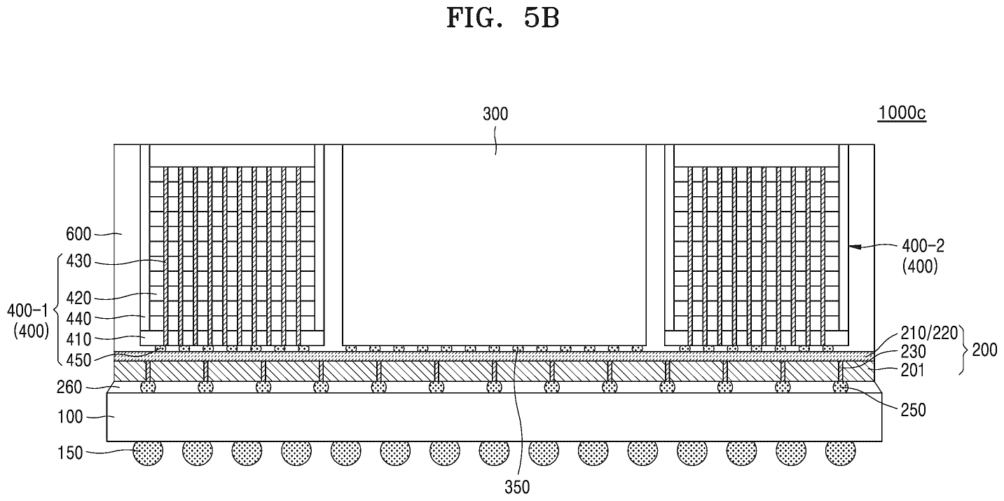

FIGS. 5A and 5B are a perspective view and a cross-sectional view, respectively, of a semiconductor package 1000c according to some example embodiments, and FIG. 5B may correspond to a cross-sectional view of the semiconductor package 1000c, taken along line I-I′ of FIG. 5A. FIGS. 6A and 6B are perspective views illustrating an SoC or chiplet included in the semiconductor package 1000c of FIG. 5A. FIG. 1A is also referred to for descriptions, and descriptions already given above with reference to FIGS. 1A to 4B are briefly provided or omitted.

Referring to FIGS. 5A to 6B, the semiconductor package 1000c according to some example embodiments may include a package substrate 100, an interposer 200, a first semiconductor device 300, a second semiconductor device 400, and an external sealant 600. The package substrate 100, the interposer 200, the first semiconductor device 300, and the second semiconductor device 400 are as described in the description of the semiconductor package 1000 according to some example embodiments of FIG. 1A.

As illustrated in FIG. 5A, in the semiconductor package 1000c according to some example embodiments, the first semiconductor device 300 may be arranged in a central portion of the interposer 200 through a second connection terminal 350. In addition, four second semiconductor devices 400 may be arranged on the interposer 200. For example, two second semiconductor devices 400 may be arranged on the interposer 200 on each side of the first semiconductor device 300. However, in the semiconductor package 1000c according to some example embodiments, the number of second semiconductor devices 400 is not limited to four. For example, one to three, or five or more second semiconductor devices 400 may be arranged on the interposer 200. The second semiconductor device 400 may be same as or similar in some respects to the second semiconductor device 400b of FIG. 3C. However, compared to the second semiconductor device 400b of FIG. 3C, in the second semiconductor device 400, ‘a’ is deleted from the reference numerals of the components, and the second semiconductor device 400 may include 12 core chips 420.

The interposer 200 in the semiconductor package 1000c of FIG. 5B may be same as or similar in some respects to the interposer 200 of the semiconductor package 1000 of FIG. 1A. In the semiconductor package 1000c of FIG. 5B, an active layer 210 and a wiring layer 220 are indicated together as ‘210/220’, and an internal selection circuit and wirings are not shown. An underfill 260 may be filled between the interposer 200 and the package substrate 100 and between the first connection terminals 250. In some example embodiments, the underfill 260 may be replaced with an adhesive layer or an adhesive film.

In the semiconductor package 1000c according to some example embodiments, the first semiconductor device 300 may have a chip structure, but may have an SoC structure or a chiplet structure. The SoC structure may have a structure in which multiple systems are integrated into a single chip, as illustrated in FIG. 6A. Accordingly, the first semiconductor device 300 having the SoC structure may be configured or programmed to solve computational functions, data storage, analog and digital signal conversion, etc. within a single chip. For example, the first semiconductor device 300 having the SoC structure of FIG. 6A may include a CPU region 310, a GPU region 320, an input/output (I/O) region 330, a communication region 340, a remaining region 370, etc. within the first semiconductor device 300.

The chiplet structure may have a structure in which a logic chip is divided into separate chips by function, as illustrated in FIG. 6B, and the separate chips are connected to each other. For example, the first semiconductor device 300a having the chiplet structure of FIG. 6B may include a CPU chip 310a, a GPU chip 320a, an I/O chip 330a, a communication modem chip 340a, other function chip 370a, etc. The first semiconductor device 300a having the chiplet structure may overcome the performance limitations of a single chip.

The external sealant 600 may cover and seal the first semiconductor device 300 and the second semiconductor device 400 on the interposer 200. As shown in FIG. 5B, the external sealant 600 may not cover the upper surfaces of the first semiconductor device 300 and the second semiconductor devices 400. However, in other embodiments, the external sealant 600 may cover at least one of the upper surfaces of the first semiconductor device 300 and the second semiconductor devices 400. Although not shown in the drawings, the semiconductor package 1000c according to some example embodiments may further include a second external sealant that covers and seals the interposer 200 and the external sealant 600 on the package substrate 100.

For reference, the structure of the semiconductor package 1000c according to some example embodiments may be referred to as a 2.5D package structure, and the 2.5D package structure may correspond to a relative concept to a 3D package structure in which all semiconductor chips are stacked together and there is no interposer. Both the 2.5D package structure and the 3D package structure may be included in a System-In-Package (SIP) structure.

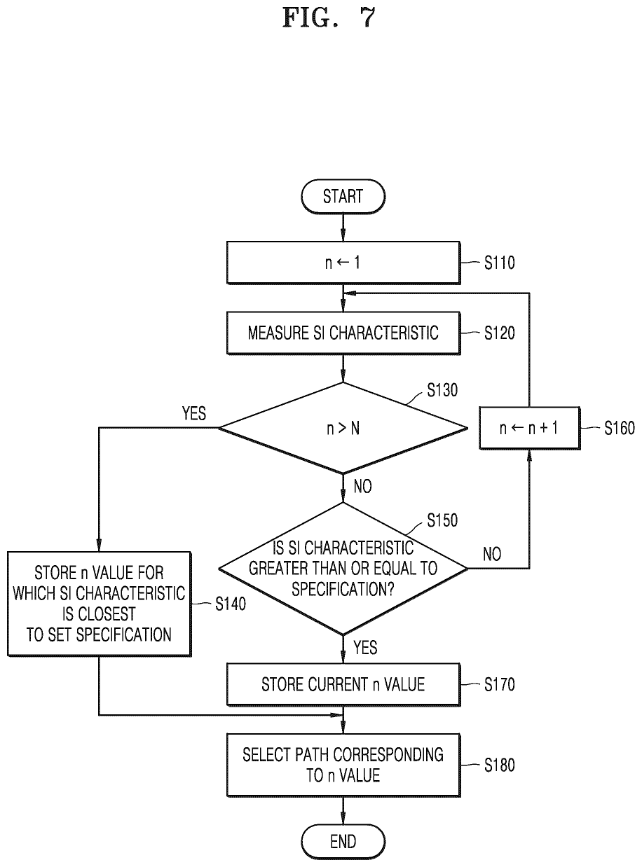

FIG. 7 is a flowchart schematically showing a method of optimizing the impedance of a semiconductor package, according to some example embodiments. The method will be described with reference to FIGS. 1A and 1B, and may be best understood with reference to FIGS. 1A to 6B. It is understood that additional operations can be provided before, during, and after the operations in FIG. 7, and some of the operations described below can be replaced or eliminated, for additional embodiments of the method. The order of the operations/processes may be interchangeable, or two or more operations can be performed simultaneously.

Referring to FIG. 7, the method of determining an impedance of a semiconductor package (hereinafter, referred to as an ‘impedance optimization method’), according to some example embodiments, may determine an optimal impedance of the semiconductor package 1000 of FIG. 1A. The semiconductor package 1000 may include the selection circuit 214, and the wirings 224, which form n paths, in the interposer 200. It will be understood that the impedance optimization method is not limited to only the semiconductor package 1000 of FIG. 1A. The impedance optimization method according to example embodiments, may be equally applicable to the semiconductor package 1000a of FIG. 4A, the semiconductor package 1000b of FIG. 4B, and/or the semiconductor package 1000c of FIGS. 5A and 5B.

In the impedance optimization method, in operation S110, a path variable n is initialized to a value 2. The path variable n represents the number of paths that may be selected in the selection circuit 214 and may be an integer that is 2 or more. The path corresponding to n=2 may correspond to a path set as a default.

In operation S120, the SI characteristic is measured for the path corresponding to n=2, for example, the default path. In operation S130, it is determined whether n is greater than N. In some example embodiments, N may correspond to the total number of paths. For example, when the total number of paths is 5, N may be 5. In operation S140, when n is greater than N (YES), an n value corresponding to the path variable for which the measured SI characteristic is closest (e.g., within a desired percentage or threshold) to a set specification (or, alternatively, a desired or predetermined value) from among 1 to N is stored.

When n is less than or equal to N (NO), in operation S150, it is determined whether the measured SI characteristic is greater than or equal to the set specification. When the measured SI characteristic is less than the set specification (NO), in operation S160, n is increased by 1, and the method again measures the SI characteristic, as in operation S120. When the measured SI characteristic is greater than or equal to the set specification (YES), in operation S170, the n value corresponding to the current path variable is stored.

In operation S180, a path corresponding to the stored n value is selected through the selection circuit 214.

The impedance optimization method, according to some example embodiments, may enable a relatively higher-performance semiconductor package to be implemented by reducing SI characteristic degradation and margin reduction by storing an n value that satisfies or is closest to a set specification through the above-described method and selecting a path corresponding to the stored n value through the selection circuit 214.

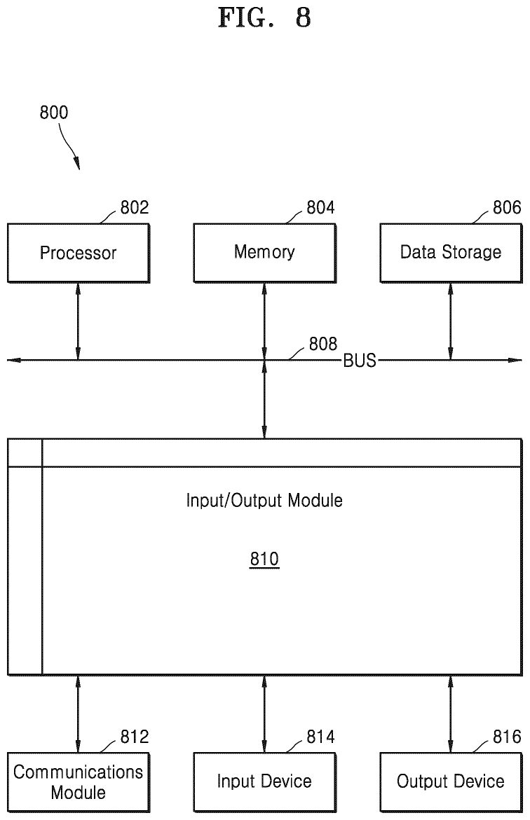

FIG. 8 is a block diagram illustrating an example computer system 800 for implementing the method and operations illustrated in FIG. 7, and other tasks described herein, according to some example embodiments. According to some example embodiments, the computer system 800 may perform the method in FIG. 7 to determine an optimal impedance of the semiconductor package 1000 of FIG. 1A, the semiconductor package 1000a of FIG. 4A, the semiconductor package 1000b of FIG. 4B, and/or the semiconductor package 1000c of FIGS. 5A and 5B. In some example embodiments, computer system 800 may be implemented using hardware or a combination of software and hardware, either in a dedicated server, integrated into another entity, or distributed across multiple entities.

Computer system 800 includes a bus 808 or other communication mechanism for communicating information, and a processor 802 coupled with bus 808 for processing information. By way of example, computer system 800 can be implemented with one or more processors 802. Processor 802 can be a microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable entity that can perform calculations or other manipulations of information.

Computer system 800 includes, in addition to hardware, code that creates an execution environment for the computer program in question, e.g., code that constitutes processor firmware, a protocol stack, a database management system, an operating system, or a combination of one or more of them stored in an included memory 804, such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device, coupled to bus 808 for storing information and instructions to be executed by processor 802. Processor 802 and memory 804 can be supplemented by, or incorporated in, special purpose logic circuitry.

The memory 804 may store an instruction program, and the processor 802 may perform a function (e.g., methods and operations illustrated in FIG. 7) by executing the stored instruction program.

The instructions may be stored in memory 804 and implemented in one or more computer program products, e.g., one or more modules of computer program instructions encoded on a computer readable medium for execution by, or to control the operation of, the computer system 800. The instructions may include a computer program, a code, or any combination thereof, and may transform the processor 802 for a special purpose by instructing and/or configuring the processor independently or collectively to operate as desired. Memory 804 may also be used for storing temporary variable or other intermediate information during execution of instructions to be executed by processor 802.

Computer system 800 further includes a data storage device 806 such as a magnetic disk or optical disk, coupled to bus 808 for storing information and instructions.

Computer system 800 is coupled via input/output module 810 to various devices. The input/output module 810 is any input/output module. Example input/output modules 810 include data ports such as USB ports. The input/output module 810 is configured to connect to a communications module 812. Example communications modules 812 include networking interface cards, such as Ethernet cards and modems, or other communication devices for wired or wireless communication. In certain aspects, the input/output module 810 is configured to connect to a plurality of devices, such as an input device 814 and/or an output device 816. Example input devices 814 include a keyboard and a pointing device, e.g., a mouse or a trackball, by which a user can provide input to the computer system 800. Example output devices 816 include display devices, such as a LED (light emitting diode), CRT (cathode ray tube), or LCD (liquid crystal display) screen, for displaying information to the user.

Methods as disclosed herein may be performed by computer system 800 in response to processor 802 executing one or more sequences of one or more instructions contained in memory 804. Such instructions may be read into memory 804 from another machine-readable medium, such as data storage device 806. Execution of the sequences of instructions contained in memory 804 causes processor 802 to perform the operations and other tasks described herein. One or more processors in a multi-processing arrangement may also be employed to execute the sequences of instructions contained in memory 804. In alternative aspects, hard-wired circuitry may be used in place of or in combination with software instructions to implement various aspects of the present disclosure. Thus, aspects of the present disclosure are not limited to any specific combination of hardware circuitry and software.

Computer system 800 includes servers and personal computer devices. A personal computing device and server are generally remote from each other and typically interact through a communication network. The relationship of client and server arises by virtue of computer programs running on the respective computers and having a client-server relationship to each other. Computer system 800 can be, for example, and without limitation, a desktop computer, laptop computer, or tablet computer.

The term “machine-readable storage medium” or “computer readable medium” as used herein refers to any medium or media that participates in providing instructions or data to processor 802 for execution. Such a medium may take many forms, including, but not limited to, non-volatile media, volatile media, and transmission media. Non-volatile media include, for example, optical disks, magnetic disks, or flash memory, such as data storage device 806. Volatile media include dynamic memory, such as memory 804. Transmission media include coaxial cables, copper wire, and fiber optics, including the wires that comprise bus 808. Common forms of machine-readable media include, for example, floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH EPROM, any other memory chip or cartridge, or any other medium from which a computer can read. The machine-readable storage medium can be a machine-readable storage device, a machine-readable storage substrate, a memory device, a composition of matter effecting a machine-readable propagated signal, or a combination of one or more of them.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor package comprising:
a package substrate;
a mediate substrate on the package substrate and including an active layer and a wiring layer; and
at least two semiconductor devices on the mediate substrate,
wherein the wiring layer includes path wirings configured to connect the at least two semiconductor devices to each other, the path wirings including n paths (n is an integer that is 2 or more), and
the active layer includes a selection circuit configured to select one of the n paths.

2. The semiconductor package of claim 1, wherein the semiconductor package has an impedance from a range of impedances that are based on path selection by the selection circuit.

3. The semiconductor package of claim 1, wherein the at least two semiconductor devices include a first semiconductor device and a second semiconductor device, and
wherein the selection circuit includes a demultiplexer (DEMUX) connected to the first semiconductor device and a multiplexer (MUX) connected to the second semiconductor device.

4. The semiconductor package of claim 3, wherein the wiring layer includes first wirings between the first semiconductor device and the DEMUX, the path wirings between the DEMUX and the MUX, and second wirings between the second semiconductor device and the MUX.

5. The semiconductor package of claim 3, further comprising a control wiring connected to the selection circuit to control the selection circuit.

6. The semiconductor package of claim 5, wherein the control wiring is connected to one of the first semiconductor device, the second semiconductor device, and an external connection terminal of the package substrate.

7. The semiconductor package of claim 3, wherein both the first semiconductor device and the second semiconductor device include logic devices.

8. The semiconductor package of claim 3, wherein one of the first semiconductor device and the second semiconductor device includes a logic device and the other of the first semiconductor device and the second semiconductor device includes a memory device.

9. The semiconductor package of claim 3, wherein one of the first semiconductor device and the second semiconductor device includes a logic device and the other of the first semiconductor device and the second semiconductor device is a memory device, and
wherein the memory device has a package structure including a plurality of memory chips.

10. The semiconductor package of claim 3, wherein at least one of the first semiconductor device and the second semiconductor device is a logic device, and
wherein the logic device has a System on Chip (SoC) structure or a chiplet structure including a plurality of logic chips.

11. The semiconductor package of claim 1, wherein the mediate substrate includes a silicon (Si)-interposer, and
wherein the Si-interposer includes a Si-substrate, the active layer on the Si-substrate, and the wiring layer on the active layer.

12. The semiconductor package of claim 1, wherein the mediate substrate includes a redistribution substrate and a Si-bridge in the redistribution substrate, and
wherein the path wirings and the selection circuit are in the Si-bridge.

13. A semiconductor package comprising:
a package substrate;
a mediate substrate on the package substrate and including an active layer and a wiring layer;
a first semiconductor device on the mediate substrate; and
a second semiconductor device adjacent to the first semiconductor device and on the mediate substrate, wherein
the wiring layer includes path wirings configured to connect the first semiconductor device and the second semiconductor device to each other, the path wirings including n paths (n is an integer that is 2 or more),
the active layer includes a demultiplexer (DEMUX) connected to the first semiconductor device and a multiplexer (MUX) connected to the second semiconductor device, and
one of the n paths is selected through the DEMUX and the MUX, the selected path having an impedance from a range of impedances.

14. The semiconductor package of claim 13, further comprising a control wiring configured to apply a selection signal to the DEMUX and the MUX,
wherein the control wiring is connected to one of the first semiconductor device, the second semiconductor device, and an external connection terminal of the package substrate.

15. The semiconductor package of claim 13, wherein the first semiconductor device and the second semiconductor device are both logic devices.

16. The semiconductor package of claim 13, wherein one of the first semiconductor device and the second semiconductor device is a logic device and the other of the first semiconductor device and the second semiconductor device is a memory device.

17. (canceled)

18. A semiconductor package comprising:
a package substrate;
at least two semiconductor devices on the package substrate; and
a path substrate including path wirings and a selection circuit, the path wirings connecting the at least two semiconductor devices to each other, the path wirings including n paths (n is an integer that is 2 or more) and the selection circuit configured to select one of the n paths,
wherein the semiconductor package has an impedance from a range of impedances, the range of impedances being based on path selection by the selection circuit.

19. The semiconductor package of claim 18, wherein the path substrate includes a mediate substrate on the package substrate and including an active layer and a wiring layer, and
wherein the at least two semiconductor devices are on the mediate substrate, and the path wirings are in the wiring layer and the selection circuit is in the active layer.

20. (canceled)

21. The semiconductor package of claim 18, wherein the path substrate includes a Si-bridge in the package substrate and including an active layer and a wiring layer, and
wherein the path wirings are in the wiring layer and the selection circuit is in the active layer.

22. The semiconductor package of claim 18, wherein the at least two semiconductor devices include a first semiconductor device and a second semiconductor device, and the selection circuit includes a demultiplexer (DEMUX) connected to the first semiconductor device and a multiplexer (MUX) connected to the second semiconductor device, and
wherein the first semiconductor device and the second semiconductor device are both logic devices, or one of the first semiconductor device and the second semiconductor device is a logic device and the other of the first semiconductor device and the second semiconductor device is a memory device.
